(19) United States
(12) Patent Application Publication
(10) Pub. No.: US 2018/0151712 A1
(43) Pub. Date: May 31, 2018

(54) ENHANCEMENT MODE HEMT DEVICE

(71) Applicant: Nuvoton Technology Corporation, Hsinchu (TW)

(72) Inventors: Vivek Ningaraju, Hsinchu (TW); Po-An Chen, Hsinchu (TW)

(73) Assignee: Nuvoton Technology Corporation, Hsinchu (TW)

(21) Appl. No.: 15/691,761

(22) Filed: Aug. 31, 2017

(30) Foreign Application Priority Data
Nov. 29, 2016 (TW) 105139205

(51) Int. Cl. H01L 29/778; H01L 29/40; H01L 29/06

(52) U.S. Cl. CPC H01L 29/7786; H01L 29/0615; H01L 29/402

(57) ABSTRACT

Provided is an enhancement mode HEMT device including a substrate, a channel layer, a barrier layer, a nitride field plate, a P-type semiconductor layer, a gate electrode, a source electrode and a drain electrode. The channel layer is disposed on a substrate. The barrier layer is disposed on the channel layer. The nitride field plate is disposed on the barrier layer and includes a main pattern and a plurality of auxiliary patterns aside the main pattern. The P-type semiconductor layer is disposed on the main pattern of the nitride field plate. The gate electrode is disposed on the P-type semiconductor layer. The source electrode and the drain electrode are disposed on the barrier layer beside the gate electrode.

### CROSS-REFERENCE TO RELATED APPLICATION

This application claims the priority benefit of Taiwan application serial no. 105139205, filed on Nov. 29, 2016. The entirety of the above-mentioned patent application is hereby incorporated by reference herein and made a part of this specification.

### BACKGROUND OF THE INVENTION

### Field of Invention

The present disclosure relates to a semiconductor device, and more particularly to an enhancement mode high electron mobility transistor (HEMT) device.

### Description of Related Art

In recent years, group III-V compound semiconductor based HEMT devices have been widely applied in high power electronic devices due to their low resistance, high breakdown voltage and fast switch speed, etc.

Generally speaking, HEMT devices can be classified into depletion mode or normally on transistor devices, and enhancement mode or normally off transistor devices. The enhancement mode transistor devices have been drawn high attention in the industry because of the added safety and because they are easier to control with simple and low cost driving circuits.

### SUMMARY OF THE INVENTION

Accordingly, the present disclosure provides an enhancement mode HEMT device, in which a nitride field plate is disposed between a P-type semiconductor layer and a barrier layer, so as to effectively spread the electric field and therefore improve the device reliability.

The present disclosure provides an enhancement mode HEMT device including a substrate, a channel layer, a barrier layer, a nitride field plate, a P-type semiconductor layer, a gate electrode, a source electrode and a drain electrode. The channel layer is disposed on a substrate. The barrier layer is disposed on the channel layer. The nitride field plate is disposed on the barrier layer and includes a main pattern and a plurality of auxiliary patterns aside the main pattern. The P-type semiconductor layer is disposed on the main pattern of the nitride field plate. The gate electrode is disposed on the P-type semiconductor layer. The source electrode and the drain electrode are disposed on the barrier layer beside the gate electrode.

According to an embodiment of the present disclosure, the auxiliary patterns of the nitride field plate are disposed on the barrier layer between the gate electrode and the drain electrode.

According to an embodiment of the present disclosure, the auxiliary patterns of the nitride field plate have a substantially equal width.

According to an embodiment of the present invention, widths of the auxiliary patterns of the nitride field plate are gradually decreased toward the drain electrode.

According to an embodiment of the present invention, a width of the main pattern is greater than a width of at least one of the auxiliary patterns of the nitride field plate.

According to an embodiment of the present invention, the auxiliary patterns of the nitride field plate have a substantially equal thickness.

According to an embodiment of the present invention, thicknesses of the auxiliary patterns of the nitride field plate are gradually decreased toward the drain electrode.

According to an embodiment of the present invention, a thickness of the main pattern is greater than or equal to a thickness of at least one of the auxiliary patterns of the nitride field plate.

According to an embodiment of the present invention, the auxiliary patterns of the nitride field plate have a substantially equal doping concentration.

According to an embodiment of the present invention, doping concentrations of the auxiliary patterns of the nitride field plate are gradually decreased toward the drain electrode.

According to an embodiment of the present invention, a doping concentration of the main pattern is greater than or equal to a doping concentration of at least one of the auxiliary patterns of the nitride field plate.

According to an embodiment of the present invention, an average doping concentration of the nitride field plate is lower than an average doping concentration of the P-type semiconductor layer.

According to an embodiment of the present invention, a gap between two adjacent auxiliary patterns of the nitride field plate is substantially equal.

According to an embodiment of the present invention, a gap between two adjacent auxiliary patterns of the nitride field plate is gradually decreased toward the drain electrode.

According to an embodiment of the present invention, a boundary of the main pattern of the nitride field plate is protruded from a boundary of the P-type semiconductor layer, and another boundary of the main pattern of the nitride field plate is aligned to another boundary of the P-type semiconductor layer.

According to an embodiment of the present invention, a composition of the barrier layer is substantially the same as a composition of the nitride field plate.

According to an embodiment of the present invention, the barrier layer is undoped while the nitride field plate is doped with a P-type dopant.

According to an embodiment of the present invention, a thickness of the nitride field plate ranges from about 20 angstroms to 400 angstroms.

According to an embodiment of the present invention, a doping concentration of the nitride field plate ranges from about 10¹⁵ atom/cm³ to 10¹⁸ atom/cm³.

According to an embodiment of the present invention, a material of the nitride field plate includes AlGaN, AlInN, AlN or AlGaInN or a combination thereof.

In view of the above, a nitride field plate is introduced to an enhancement mode HEMT device for effectively spreading the electric field and improving the device reliability. Specifically, the nitride field plate of the invention has a main pattern protruding from a P-type semiconductor layer and multiple auxiliary patterns between a gate electrode and a drain electrode. The main pattern is configured to reduce the electric field at the corner of the gate electrode. The auxiliary patterns are configured to form a region with a reduced two dimensional electron gas (2DEG) density. Such disposition is beneficial to relieve an electric field, improve a breakdown voltage and reduce a leakage current.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 to FIG. 8 are schematic cross-sectional views of various enhancement mode HEMT devices according to some embodiments of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

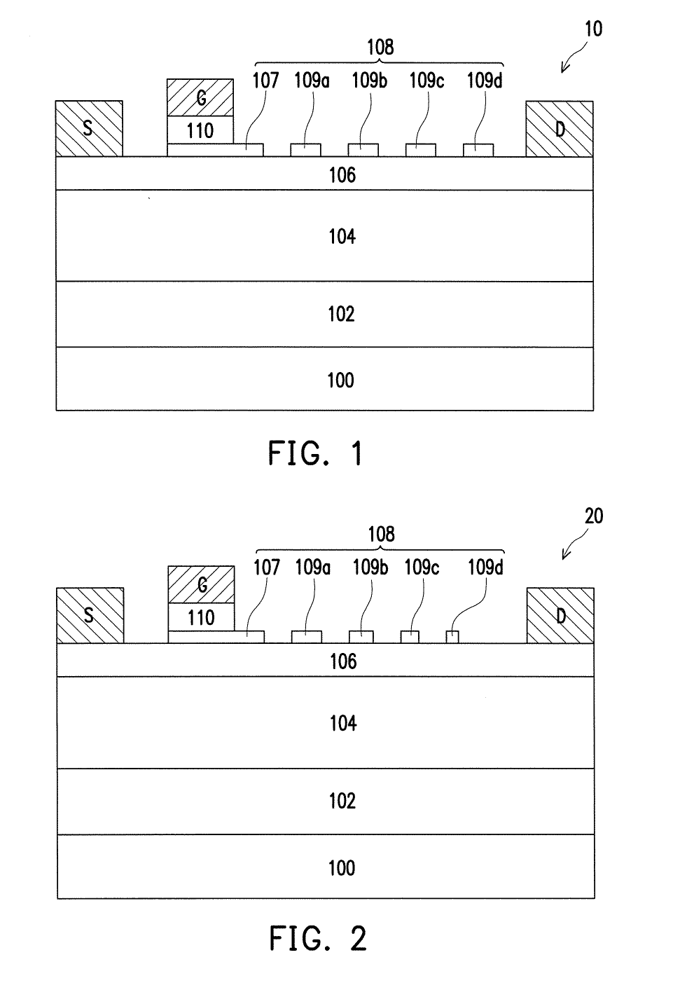

FIG. 1 to FIG. 8 are schematic cross-sectional views of various enhancement mode HEMT devices according to some embodiments of the present invention. The enhancement mode HEMT devices of FIG. 1 to FIG. 8 are similar to each other, and the differences between them lie in the pattern distributions, thicknesses, doping concentrations and/or similar parameters of the nitride field plates. The differences are illustrated in details below.

Referring to FIG. 1 to FIG. 8, an enhancement mode HEMT device of the invention includes a substrate 100, a buffer layer 102, a channel layer 104, a barrier layer 106, a P-type semiconductor layer 110, a gate electrode G, a source electrode S and a drain electrode D.

The channel layer 104 is formed on the substrate 100. In an embodiment, the material of the substrate 100 includes sapphire, Si, SiC or GaN. In an embodiment, the material of the channel layer 104 includes a group III nitride, such as a group III-V compound semiconductor material. In an embodiment, the material of the channel layer 104 includes GaN. Besides, the channel layer 104 can be a doped layer or an undoped layer.

The buffer layer 102 can be disposed between the substrate 100 and the channel layer 104. The buffer layer 102 is configured to alleviate a lattice constant difference and a thermal expansion coefficient difference between the substrate 100 and the channel layer 104. In an embodiment, the material of the buffer layer 102 includes a group III nitride, such as group III-V compound semiconductor material, and has a single-layer or multi-layer structure. In an embodiment, the material of the buffer layer includes AlN, GaN, AlGaN, InGaN, AlInN, AlGaInN or a combination thereof.

The barrier layer 106 is disposed on the channel layer 104. In an embodiment, the barrier layer 106 includes a group III nitride, such as group III-V compound semiconductor material, and has a single-layer or multi-layer structure. In an embodiment, the material of the barrier layer 106 includes AlGaN, AlInN, AlN or AlGaInN or a combination thereof. In an embodiment, the barrier layer 106 can be a doped layer or an undoped layer.

The gate electrode G is disposed on the barrier layer 106. The gate electrode G includes a metal or a metal nitride (such as Ta, TaN, Ti, TiN, W, Pd, Ni, Au, Al or a combination thereof), a metal silicide (such as WSiₓ), or a material which can form a Schottky contact with a group III-V compound semiconductor.

The source electrode S and the drain electrode D both are disposed on the barrier layer 106 beside the gate electrode G, as shown in FIG. 1 to FIG. 8. However, the present invention is not limited thereto. In another embodiment, at least one of the source electrode S and the drain electrode D extends into the channel layer 104 and is electrically connected to a two dimensional electron gas (2DEG) region. Each of the source electrode S and the drain electrode D includes a metal (such as Al, Ti, Ni, Au or an alloy thereof), or a material which can form an Ohmic contact with a group III-V compound semiconductor.

The P-type semiconductor layer 110 is disposed between the barrier layer 106 and the gate electrode G. The P-type semiconductor layer 110 is configured to form a cut-off region of the 2DEG or a region with a relatively low electron density. In an embodiment, the material of the P-type semiconductor layer 110 includes a group III nitride, such as a group III-V compound semiconductor material. In an embodiment, the P-type semiconductor layer 110 includes GaN, AlGaN, InN, AlInN, InGaN or AlInGaN, and is doped with a P-type dopant (such as Mg). In an embodiment, the P-type semiconductor layer 110 can be a P-type GaN layer or a P-type AlₓGa₁₋ₓN layer, wherein x is from 0 to 1, such as from 0.05 to 1. In an embodiment, the P-type semiconductor layer 110 has a thickness from about 100 angstroms to 3,000 angstroms and a doping concentration from about 10¹⁸ to 10²¹ atom/cm³.

It is noted that, each enhancement mode HEMT device of the invention further includes a nitride field plate 108 for reducing the high electric field at the gate corner, preventing current leakage and therefore improving the device reliability. In an embodiment, the nitride field plate 108 is disposed on the barrier layer 106 and includes a main pattern 107 and a plurality of auxiliary patterns 109a to 109d aside the main pattern 107. In an embodiment, the P-type semiconductor layer 110 is disposed on the main pattern 107 of the nitride field plate 108. Specifically, a boundary of the main pattern 107 of the nitride field plate 108 is protruded from a boundary of the P-type semiconductor layer 110, and another boundary of the main pattern 107 of the nitride field plate 108 is aligned to another boundary of the P-type semiconductor layer 110.

Besides, the auxiliary patterns 109a to 109d of the nitride field plate 108 are disposed on the barrier layer 106 between the gate electrode G and the drain electrode D. The auxiliary patterns 109a to 109d of the nitride field plate 108 are configured to uniformly disperse the accumulation of high electric field between the gate electrode and the drain electrode.

In an embodiment, the material of the nitride field plate 108 includes a group III nitride, such as group III-V compound semiconductor material. In an embodiment, the nitride field plate 108 includes AlGaN, AlInN, AlN or AlGaInN or a combination thereof, and is doped with a P-type dopant (such as Mg). In an embodiment, the barrier layer 106 has a composition substantially the same as that of the nitride field plate 108. In an embodiment, the barrier layer 106 and the nitride field plate 108 include substantially the same elements of composition, and the difference between them merely lies in the doping concentration. In an embodiment, the barrier layer 106 and the nitride field plate 108 are made by the same material, wherein the barrier layer 106 is undoped while the nitride field plate 108 is doped with a P-type dopant.

In an embodiment, each of the barrier layer 106 and the nitride field plate 108 includes Al_{y}Ga_{1-y}N, wherein y is from 0 to 1, such as from 0.1 to 1. In another embodiment, the barrier layer 106 includes Al_{y}Ga_{1-y}N and the nitride field plate 108 includes Al_{z}Ga_{1-z}N, wherein each of y and z is from 0 to 1, and y is not equal to z. In an embodiment, y is greater than z. In another embodiment, y is smaller than z.

In an embodiment, the nitride field plate 108 has a thickness of about 20 angstroms to 400 angstroms and a doping concentration of about 10¹⁵ to 10¹⁸ atom/cm³. In an embodiment, the average doping concentration of the nitride field plate 108 is lower than the average doping concentration of the P-type semiconductor layer 110.

In an embodiment, the auxiliary patterns 109a to 109d of the nitride field plate 108 have a substantially equal width, as shown in the enhancement mode HEMT device 10 of FIG. 1. In another embodiment, widths of the auxiliary patterns 109a to 109d of the nitride field plate 108 are gradually decreased toward the drain electrode D, as shown in the enhancement mode HEMT device 20 of FIG. 2. Specifically, as shown in FIG. 2, the width of the auxiliary pattern 109a is greater than the width of the auxiliary pattern 109b, the width of the auxiliary pattern 109b is greater than the width of the auxiliary pattern 109c, and the width of the auxiliary pattern 109c is greater than the width of the auxiliary pattern 109d. Besides, the width of the main pattern 107 is greater than the width of at least one of the auxiliary patterns 109a to 109d of the nitride field plate 108.

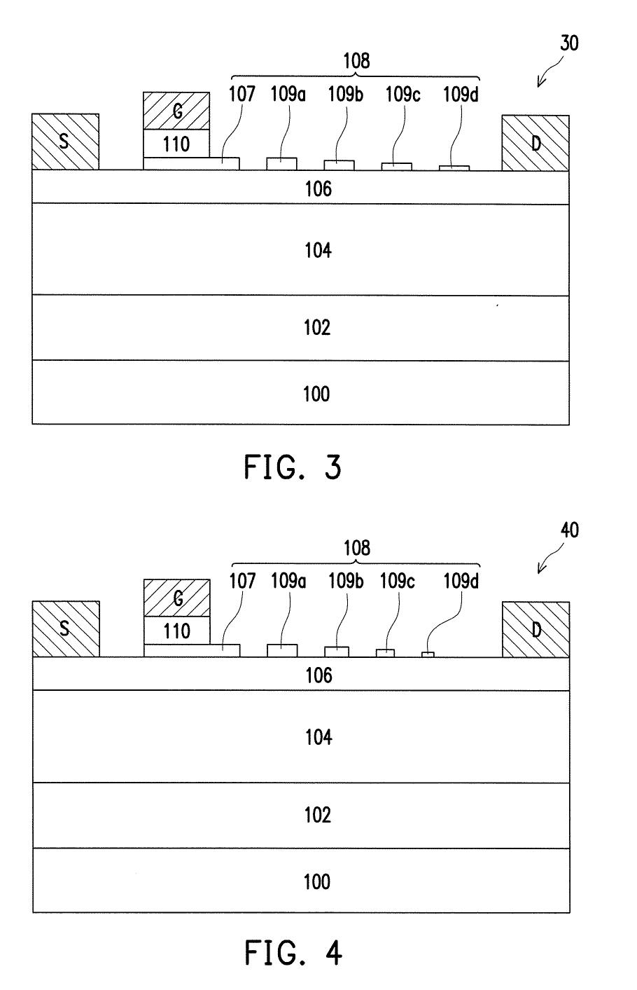

In an embodiment, the auxiliary patterns 109a to 109d of the nitride field plate 108 have a substantially equal thickness, as shown in the enhancement mode HEMT device 10 of FIG. 1 and the enhancement mode HEMT device 20 of FIG. 2. In another embodiment, thicknesses of the auxiliary patterns 109a to 109d of the nitride field plate 108 are gradually decreased toward the drain electrode D, as shown in the enhancement mode HEMT device 30 of FIG. 3 and the enhancement mode HEMT device 40 of FIG. 4. Specifically, as shown in FIG. 3 and FIG. 4, the thickness of the auxiliary pattern 109a is greater than the thickness of the auxiliary pattern 109b, the thickness of the auxiliary pattern 109b is greater than the thickness of the auxiliary pattern 109c, and the thickness of the auxiliary pattern 109c is greater than the thickness of the auxiliary pattern 109d. Besides, the thickness of the main pattern 107 is greater than or equal to the thickness of at least one of the auxiliary patterns 109a to 109d of the nitride field plate 108.

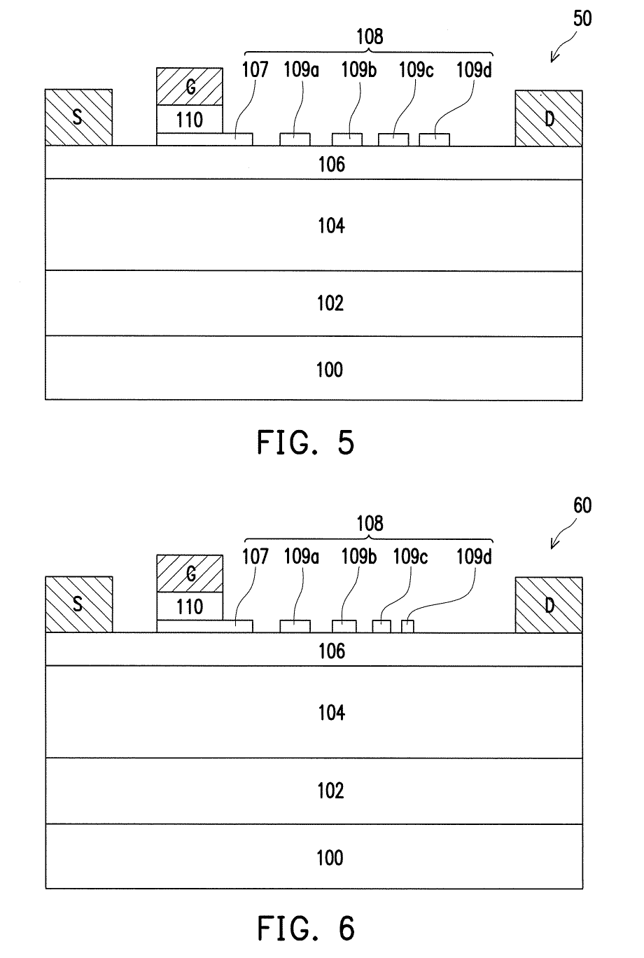

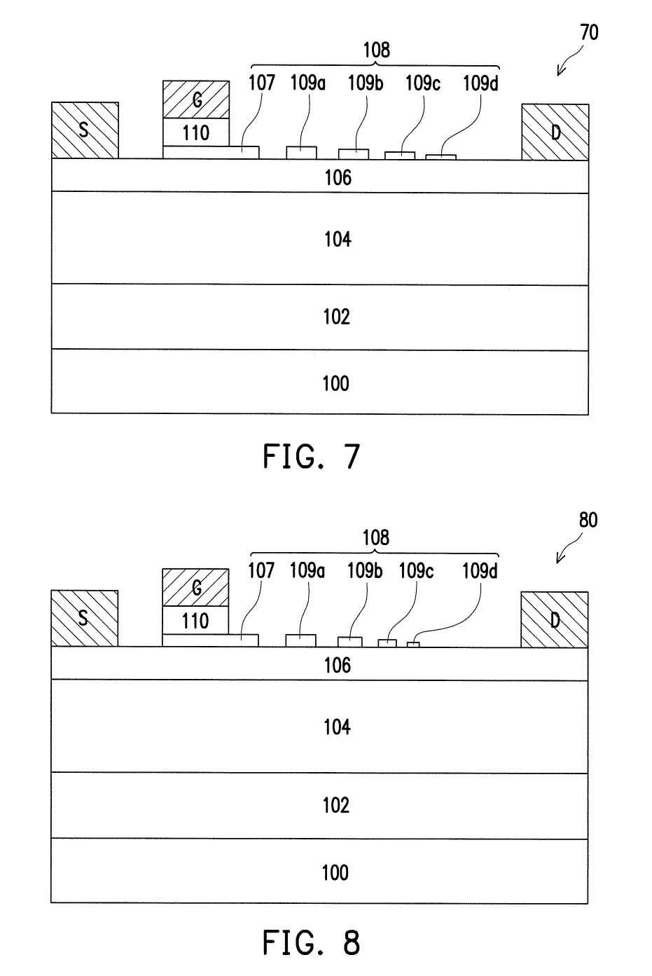

In an embodiment, a gap between adjacent two of the auxiliary patterns 109a to 109d of the nitride field plate 108 is substantially equal, as shown in the enhancement mode HEMT device 10 of FIG. 1, the enhancement mode HEMT device 20 of FIG. 2, the enhancement mode HEMT device 30 of FIG. 3 and the enhancement mode HEMT device 40 of FIG. 4. In another embodiment, a gap between adjacent two of the auxiliary patterns 109a to 109d of the nitride field plate 108 is gradually decreased toward the drain electrode D, as shown in the enhancement mode HEMT device 50 of FIG. 5, the enhancement mode HEMT device 60 of FIG. 6, the enhancement mode HEMT device 70 of FIG. 7 and the enhancement mode HEMT device 80 of FIG. 8. Specifically, as shown in FIG. 5 to FIG. 8, the gap between the auxiliary pattern 109a and the auxiliary pattern 109b is greater than the gap between the auxiliary pattern 109b and the auxiliary pattern 109c, and the gap between the auxiliary pattern 109b and the auxiliary pattern 109c is greater than the gap between the auxiliary pattern 109c and the auxiliary pattern 109d. Besides, the gap between the main pattern 107 and the auxiliary pattern 109a is greater than or equal to at least one of gaps between the auxiliary patterns 109a to 109d.

In an embodiment, the auxiliary patterns 109a to 109d of the nitride field plate 108 have a substantially equal doping concentration. In another embodiment, doping concentrations of the auxiliary patterns 109a to 109d of the nitride field plate 108 are gradually decreased toward the drain electrode D. The mentioned two doping concentration modes can be applied to the enhancement mode HEMT devices 10 to 80 of FIG. 1 to FIG. 8. Besides, the doping concentration of the main pattern 107 is greater than or equal to the doping concentration of at least one of the auxiliary patterns 109a to 109d of the nitride field plate 108.

The above embodiments in which the nitride field plate has one main pattern and four auxiliary patterns are provided for illustration purposes, and are not construed as limiting the present invention. In another embodiment, the nitride field plate of the invention can have one, two, three or more than four auxiliary patterns. In addition, the pattern distributions, thicknesses and/or doping concentrations of the auxiliary patterns of the nitride field plates are not limited by the embodiments herein, and those parameters can be adjusted upon the process requirements, as long as the electric field can be effectively dispersed and the device reliability can be greatly improved.

In summary, in the embodiments of the present invention, a P-type semiconductor layer is disposed below a gate electrode to form a depletion region of the 2DEG in a barrier layer, so as to provide an enhancement mode or normally off HEMT device. Besides, a nitride field plate is disposed between the P-type semiconductor layer and the barrier layer, so as to effectively spread the electric field and improve the device reliability. Specifically, the nitride field plate of the invention has a main pattern protruding from the P-type semiconductor layer and multiple auxiliary patterns between the gate electrode and the drain electrode. The main pattern is configured to reduce the electric field at the corner of the gate electrode. The auxiliary patterns are configured to form a region with a reduced 2DEG density. Such disposition is beneficial to relieve an electric field, improve a breakdown voltage and reduce a leakage current.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. An enhancement mode HEMT device, comprising:
a channel layer, disposed on a substrate;
a barrier layer, disposed on the channel layer;
a nitride field plate, disposed on the barrier layer and comprising a main pattern and a plurality of auxiliary patterns aside the main pattern;
a P-type semiconductor layer, disposed on the main pattern of the nitride field plate;
a gate electrode, disposed on the P-type semiconductor layer; and
a source electrode and a drain electrode, disposed on the barrier layer beside the gate electrode.

2. The enhancement mode HEMT device of claim 1, wherein the auxiliary patterns of the nitride field plate are disposed on the barrier layer between the gate electrode and the drain electrode.

3. The enhancement mode HEMT device of claim 1, wherein the auxiliary patterns of the nitride field plate have a substantially equal width.

4. The enhancement mode HEMT device of claim 1, wherein widths of the auxiliary patterns of the nitride field plate are gradually decreased toward the drain electrode.

5. The enhancement mode HEMT device of claim 1, wherein a width of the main pattern is greater than a width of at least one of the auxiliary patterns of the nitride field plate.

6. The enhancement mode HEMT device of claim 1, wherein the auxiliary patterns of the nitride field plate have a substantially equal thickness.

7. The enhancement mode HEMT device of claim 1, wherein thicknesses of the auxiliary patterns of the nitride field plate are gradually decreased toward the drain electrode.

8. The enhancement mode HEMT device of claim 1, wherein a thickness of the main pattern is greater than or equal to a thickness of at least one of the auxiliary patterns of the nitride field plate.

9. The enhancement mode HEMT device of claim 1, wherein the auxiliary patterns of the nitride field plate have a substantially equal doping concentration.

10. The enhancement mode HEMT device of claim 1, wherein doping concentrations of the auxiliary patterns of the nitride field plate are gradually decreased toward the drain electrode.

11. The enhancement mode HEMT device of claim 1, wherein a doping concentration of the main pattern is greater than or equal to a doping concentration of at least one of the auxiliary patterns of the nitride field plate.

12. The enhancement mode HEMT device of claim 1, wherein an average doping concentration of the nitride field plate is lower than an average doping concentration of the P-type semiconductor layer.

13. The enhancement mode HEMT device of claim 1, wherein a gap between two adjacent auxiliary patterns of the nitride field plate is substantially equal.

14. The enhancement mode HEMT device of claim 1, wherein a gap between two adjacent auxiliary patterns of the nitride field plate is gradually decreased toward the drain electrode.

15. The enhancement mode HEMT device of claim 1, wherein a boundary of the main pattern of the nitride field plate is protruded from a boundary of the P-type semiconductor layer, and another boundary of the main pattern of the nitride field plate is aligned to another boundary of the P-type semiconductor layer.

16. The enhancement mode HEMT device of claim 1, wherein a composition of the barrier layer is substantially the same as a composition of the nitride field plate.

17. The enhancement mode HEMT device of claim 1, wherein the barrier layer is undoped while the nitride field plate is doped with a P-type dopant.

18. The enhancement mode HEMT device of claim 1, wherein a thickness of the nitride field plate ranges from about 20 angstroms to 400 angstroms.

19. The enhancement mode HEMT device of claim 1, wherein a doping concentration of the nitride field plate ranges from about 10¹⁵ atom/cm³ to 10¹⁸ atom/cm³.

20. The enhancement mode HEMT device of claim 1, wherein a material of the nitride field plate comprises AlGaN, AlInN, AlN or AlGaInN or a combination thereof.
